(19) United States
(12) Patent Application Publication
(10) Pub. No.: US 2013/0178061 A1
(43) Pub. Date: Jul. 11, 2013

(54) METHOD OF MANUFACTURING POROUS FILM AND METHOD OF MANUFACTURING SEMICONDUCTOR DEVICE

(71) Applicant: Renesas Electronics Corporation, Kanagawa (JP)

(72) Inventors: Hironori YAMAMOTO, Kanagawa (JP); Fuminori ITO, Kanagawa (JP); Yoshihiro HAYASHI, Kanagawa (JP)

(73) Assignee: RENESAS ELECTRONICS CORPORATION, Kanagawa (JP)

(21) Appl. No.: 13/715,280

(22) Filed: Dec. 14, 2012

(30) Foreign Application Priority Data
Jan. 6, 2012 (JP) 2012-001319

(51) Int. Cl. H01L 21/3105; H01L 21/3205

(52) U.S. Cl. CPC H01L 21/3105; H01L 21/3205
USPC 438/666; 438/758

(57) ABSTRACT

First, a porous insulating film 120 is formed using an organic silica raw material containing a hydrocarbon group. The hydrocarbon group contains, for example, an unsaturated carbon compound, but may contain a saturated carbon compound. The skeleton of the organic silica is, for example, cyclic organic silica. Next, the surface of the porous insulating film 120 is subjected to plasma processing by using a processing gas containing an inactive gas and a reducing gas. Subsequently, in the porous insulating film 120, a wiring trench 123 is formed and is embedded with wiring 124.

### CROSS-REFERENCE TO RELATED APPLICATION

The disclosure of Japanese Patent Application No. 2012-001319 filed on Jan. 6, 2012 including the specification, drawings and abstract is incorporated herein by reference in its entirety.

### BACKGROUND

The present invention relates to a method of manufacturing a porous film and a method of manufacturing a semiconductor device.

Along with the progress of miniaturization of semiconductor devices, the requirement for lowering the permittivity of interlayer insulating films has been revealed. As a technique of lowering the permittivity of an interlayer insulating film, there is a technique of forming an interlayer insulating film by a porous insulating film.

Note that, in Japanese Patent No. 4160277 (Patent Document 1), there is a description of processing a low permittivity insulating film containing carbon by plasma having at least one reducing gas selected from H₂ gas diluted with N₂, CO, CO₂ and NH₃. In Japanese Patent Laid-Open Nos. 2000-332010 (Patent Document 2) and 2000-277507 (Patent Document 3), there is a description of making an insulating film be porous by vacuum annealing or plasma annealing, and after that, subjecting the surface to processing with H₂ plasma.

In Japanese Patent No. 3768480 (Patent Document 4), there is a description that a trench for embedding wiring is formed in an interlayer insulating film, and after that, plasma processing is performed using He/H₂ gas or He gas. In Japanese Patent Laid-Open No. 2009-004408 (Patent Document 5), there is a description that a trench for embedding wiring is formed, then plasma processing is performed using a gas containing hydrogen or ammonia, and after that, plasma processing is performed using a gas containing fluorocarbon.

### SUMMARY

In a process of manufacturing a semiconductor device, occasionally, there is a case where time lapses, after the formation of a porous insulating film, until processing for covering the surface thereof is performed. However, as a result of the examination by the inventor, when a porous insulating film is formed and is held in the state for a long time, it was found that there is a case where the permittivity of the porous insulating film increases. Consequently, in order to improve reliability of semiconductor devices, it is necessary to suppress the increase in the permittivity of a porous insulating film being stored for a long time.

According to an embodiment, a porous insulating film is formed through the use of an organic silica (also referred to as siloxane) raw material containing a hydrocarbon group. The surface of the porous insulating film is subjected, prior to the embedding of wiring, to plasma processing through the use of a processing gas containing an inactive gas and a reducing gas.

According to the above-mentioned embodiment, it is possible to suppress the increase in the permittivity of the porous insulating film along with the lapse of time.

### BRIEF DESCRIPTION OF THE DRAWINGS

FIGS. 1A and 1B are cross-sectional views showing the method of manufacturing a semiconductor device according to a first embodiment;

FIGS. 2A and 2B are cross-sectional views showing the method of manufacturing a semiconductor device according to the first embodiment;

FIGS. 3A and 3B are cross-sectional views showing the method of manufacturing a semiconductor device according to the first embodiment;

FIGS. 4A and 4B are cross-sectional views showing the method of manufacturing a semiconductor device according to the first embodiment;

FIG. 5 is a diagram for explaining the function and effect of the embodiment;

FIG. 6 is a diagram for explaining the function and effect of the embodiment;

FIG. 7 is a diagram showing the influence given to the initial value and subsequent increasing rate of the relative permittivity of a porous insulating film 120 by a high-frequency power for generating plasma;

FIG. 8 is a cross-sectional view showing the configuration of the semiconductor device according to a second embodiment; and

FIG. 9 is a diagram for explaining the function and effect of the embodiment.

### DETAILED DESCRIPTION

Hereinafter, embodiments of the invention will be explained using the drawings. Note that, in all the drawings, the same sign is given to the same constituent, and the explanation thereof is omitted appropriately.

### First Embodiment

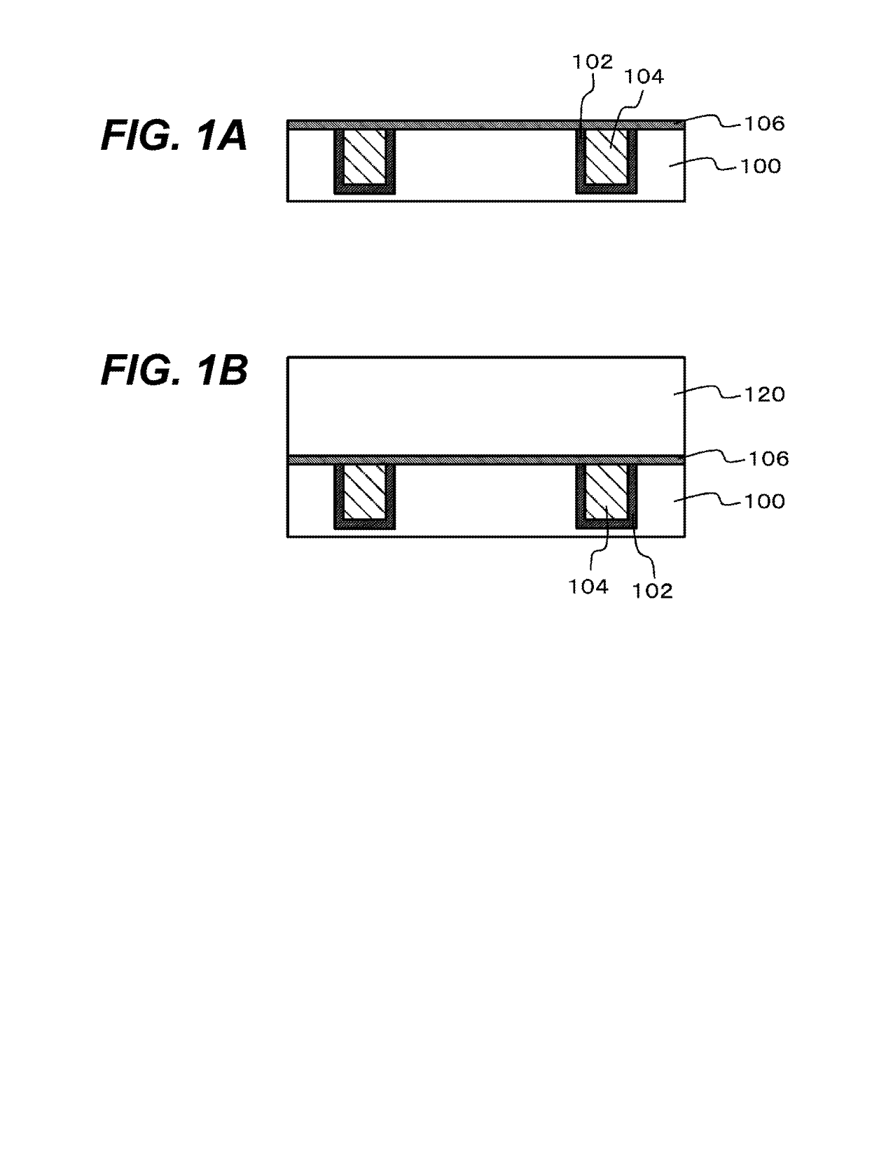

FIGS. 1 to 4 are cross-sectional views showing the method of manufacturing a semiconductor device according to a first embodiment. The method of manufacturing a semiconductor device has processes below. First, a porous insulating film 120 is formed through the use of an organic silica raw material containing a hydrocarbon group. Next, the surface of the porous insulating film 120 is subjected to plasma processing through the use of a processing gas containing an inactive gas and a reducing gas. Subsequently, in the porous insulating film 120, a wiring trench 123 is formed, and the wiring trench 123 is embedded with wiring 124. Hereinafter, the method will be explained in detail.

First, as shown in FIG. 1A, a porous insulating layer 100 is formed over a substrate. Next, in the porous insulating layer 100, a wiring trench is formed, and the side face and the bottom face of the wiring trench are covered with a barrier metal film 102. Next, the wiring trench is embedded with a wiring 104. The wiring 104 includes, for example, a metal containing copper as a main component. The barrier metal film 102 is a film for preventing the diffusion of metal elements constituting the wiring 104 into the interlayer insulating film and lower layers. When the wiring 104 includes a metal containing copper as a main component, the barrier metal film 102 includes, for example, a high melting point metal such as Ta, TaN, TiN or WCN, a nitride thereof, or a stacked film thereof. Over the surface of the wiring 104, a metal cap layer (not shown) such as a layer of CoWP, CoWB, CoSnP, CoSnB, NiB or NiMoB may be formed. Subsequently, over the porous insulating layer 100 and over the wiring 104, an insulating film 106 is formed. The insulating film 106 suppresses the diffusion of metal elements constituting the wiring 104 into the porous insulating film 120, and functions as an etching stopper when forming a via hole in the porous insulating film 120. The insulating film 106 includes, for example, a SiC film, a SiCN film, a SiN film, a BN film or a BCN film.

Next, as shown in FIG. 1B, over the insulating film 106, the porous insulating film 120 is formed. The porous insulating film 120 is formed by a plasma CVD method using an organic silica raw material containing a hydrocarbon group. The organic silica raw material is introduced using a carrier gas. The carrier gas is preferably the same as an inactive gas to be described later. In this case, it is possible to suppress the complexity of piping of an apparatus for manufacturing the porous insulating film 120.

The hydrocarbon group contains, for example, an unsaturated carbon compound, but it may contain a saturated carbon compound. Specifically, the hydrocarbon group is a vinyl group, an allyl group, a methyl group, an ethyl group, a propyl group, an isopropyl group, a butyl group or a tertiary butyl group, but is not limited to these.

The skeleton of the organic silica raw material is, for example, a cyclic organic silica raw material, but is not limited to this. When the skeleton of the organic silica raw material is cyclic organic silica, the organic silica raw material is shown by Formula (1) below.

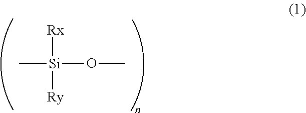

In the Formula (1), n is 2 to 5, and Rx and Ry are each any of hydrogen, an unsaturated hydrocarbon group and a saturated hydrocarbon group. Each of the unsaturated hydrocarbon group and the saturated hydrocarbon group is, for example, any of a vinyl group, an allyl group, a methyl group, an ethyl group, a propyl group, an isopropyl group, a butyl group and a tertiary butyl group.

Meanwhile, in the above-mentioned Formula (1), n may be set to 3 or 4, Rx may be set to a vinyl group and Ry may be set to an isopropyl group.

The porous insulating film 120 having been formed here has a carbon content of not less than 20% in the atom number, preferably not less than 40% in the atom number. In addition, in the porous insulating film 120, an average pore diameter is not more than 1 nm. When setting the average pore diameter of the porous insulating film 120 to be not more than 1 nm, moisture absorption of the porous insulating film 120 can be suppressed.

Here, the pore diameter of the porous insulating film 120 can be measured using, for example, a SAXS (Small Angle

X-ray Scattering) method. Specifically, when the porous insulating film 120 is irradiated with X-rays, the X-rays are led to diffuse scattering by pores in the porous insulating film 120. The scattering profile is determined according to the density and the distribution of the pore diameter in the porous insulating film 120. Therefore, on the basis of the SAXS profile, the average pore diameter in the porous insulating film 120 can be measured.

Note that, the porous insulating film 120 may be formed from an organic silica material not having a cyclic organic silica skeleton. In this case, the porous insulating film 120 is made porous by using, for example, porogen.

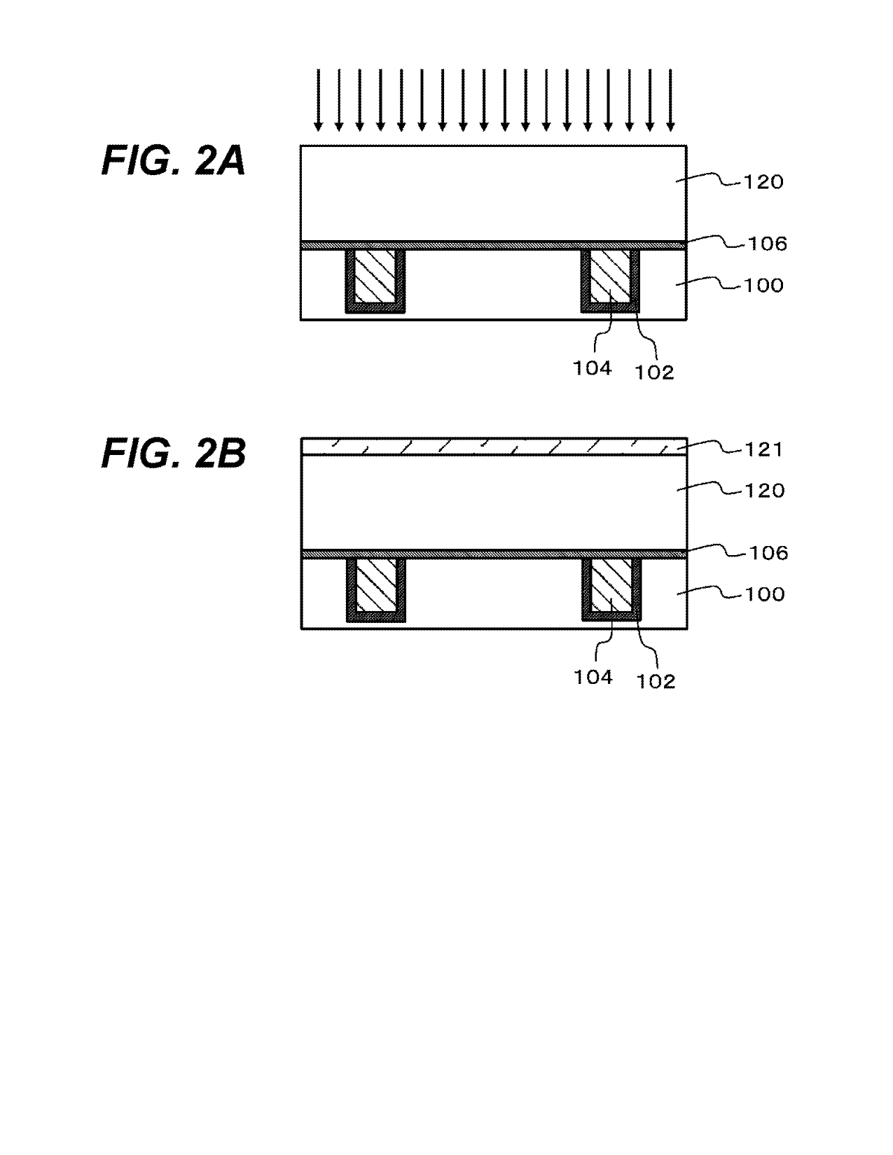

Next, as shown in FIG. 2A, the surface of the porous insulating film 120 is subjected to plasma processing using a processing gas containing an inactive gas and a reducing gas. The processing is preferably performed after the formation of the porous insulating film 120, without the exposure of the porous insulating film 120 to the air. The plasma processing is performed, for example, in the same processing vessel as that for the porous insulating film 120 in a state kept at a high vacuum continuously from the film forming processing of the porous insulating film 120. The plasma processing is performed desirably at a temperature same as the growth temperature of the porous insulating film, that is, from not less than 100° C. to 400° C. A processing time is, for example, from not less than 1 sec to not more than 30 sec. Note that, the processing time means a time period from the start of supplying power for generating plasma to the end of supplying all powers. Moreover, the power for generating plasma may be a single high frequency wave (for example, 13.56 MHz), or a combination of a high frequency wave and a low frequency wave (for example, 400 to 500 kHz).

The processing aims mainly at processing chemically the surface of the porous insulating film 120 by using ions or radicals generated from the reducing gas. Therefore, the vicinity of the surface layer of the porous insulating film 120 preferably avoids physical damages (that is, does not suffer shock by ions) as much as possible. For that purpose, the inactive gas is preferably as light as possible, for example, He. However, even when an inactive gas other than He such as Ar is used, by adjusting generation conditions of the plasma (pressure, power, interval between electrodes, etc.), it is possible to suppress damage of the porous insulating film 120. As a result, hydrocarbon components near the insulating film surface layer are kept, and thus high durability against process stresses (etching, asking, etc.) given in subsequent processes is exerted.

Furthermore, as the reducing gas, at least one of H₂, CO and NH₃ can be used. However, the reducing gas may be a gas other than these. Moreover, in the plasma processing, the ratio of the reducing gas contained in a gas to be introduced into the processing vessel is from not less than 5% to not more than 75%.

Next, as shown in FIG. 2B, over the porous insulating film 120, an insulating film 121 is formed. The insulating film 121 protects the porous insulating film 120 when a wiring 124 is embedded into the porous insulating film 120. The insulating film 121 includes, for example, a SiO₂, TEOS, or comparatively hard (Modulus: not less than 10 GPa) SiOC or SiOCH film.

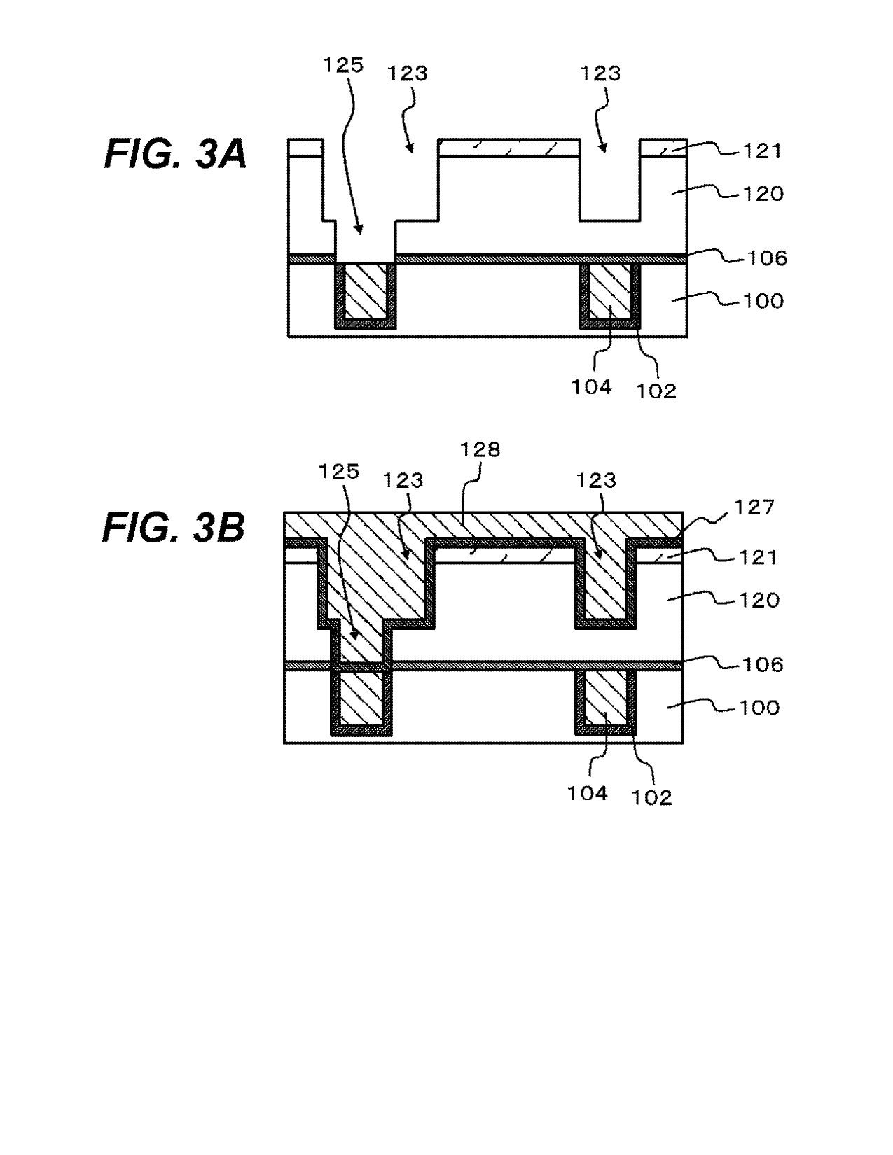

Subsequently, as shown in FIG. 3A, the porous insulating film 120 is removed selectively. Consequently, in the porous insulating film 120, the wiring trench 123 and a via hole 125 are formed. The process may be either a via first method or a trench first method.

Next, as shown in FIG. 3B, over the bottom face and the side face of the wiring trench 123 and the via hole 125, a barrier metal film 127 is formed. The material of the barrier metal film 127 is the same as the material of the barrier metal film 102. At this time, the barrier metal film 127 is formed also over the insulating film 121.

Subsequently, the inside of the wiring trench 123 and the inside of the via hole 125 are embedded with an electroconductive film 128. The electroconductive film 128 is, for example, a metal film including Cu as a main component, and is formed by, for example, a plating method. At this time, the electroconductive film 128 is formed also over the barrier metal film 127 located over the insulating film 121. After that, the electroconductive film 128 is heat-treated. Under heat treatment conditions at this time, the temperature is 200° C. to 400° C. and the time period is 30 sec to 30 min. Consequently, crystalline grains of the electroconductive film 128 grow large.

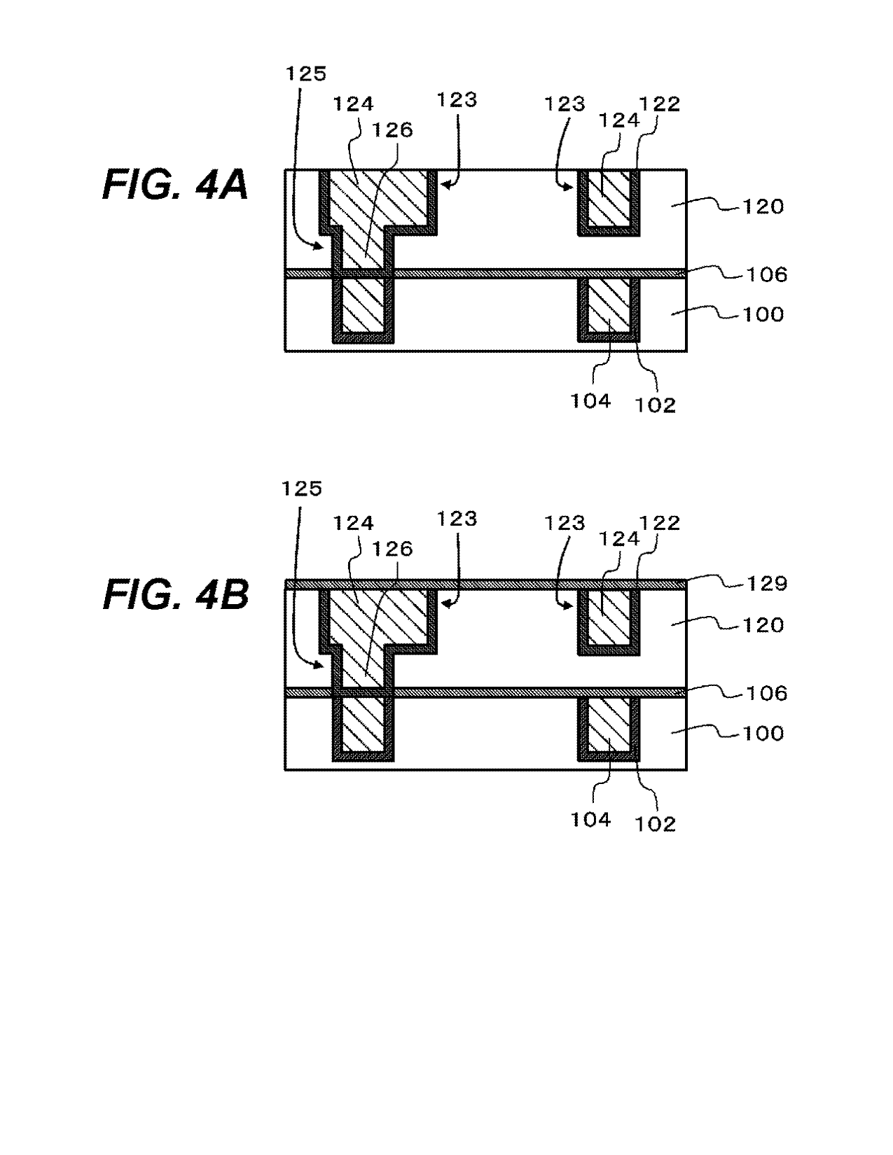

Next, as shown in FIG. 4A, the electroconductive film 128 and the barrier metal film 127 located over the insulating film 121, and the insulating film 121 are removed using a CMP method. At this time, the outermost layer of the porous insulating film 120 is also removed. Meanwhile, the wiring 124 and the via 126 are formed by a dual damascene method, but they may be formed by a single damascene method.

Subsequently, as shown in FIG. 4B, over the porous insulating film 120 and over the wiring 124, an insulating film 129 is formed. The insulating film 129 is the same film as the insulating film 106. After that, the porous insulating film 120, the wiring 124, the wiring trench 123 and the insulating film 129 are stacked in a number of necessary layers.

Meanwhile, when forming the porous insulating film 120, a plurality of organic silica raw materials may be used. Since organic materials in which n is set to 3 or 4 in the structure shown by the Formula (1) are easy to be manufactured, many of which are chemically stable, and have a relatively small cyclic skeleton structure, the use of a raw material obtained by mixing a plurality of these gives a better result.

For example, there may be used, as a first organic material, a compound in which, in the structure shown in the above-mentioned Formula (1), n is 3, Rx is a vinyl group and Ry is a methyl group (2,4,6-trimethyl-2,4,6-trivinylcyclotrisiloxane) or Rx is a vinyl group and Ry is an isopropyl group (2,4,6-triisopropyl-2,4,6-trivinylcyclotrisiloxane), and there may also be used, as a second organic material, a compound in which, in the structure shown in the above-mentioned Formula (1), n is 4, Rx is a vinyl group and Ry is an isopropyl group (2,4,6,8-tetraisopropyl-2,4,6,8-tetravinylcyclotetrasilo xane) or Rx is a vinyl group and Ry is a methyl group (2,4,6,8-tetramethyl-2,4,6,8-tetravinylcyclotetrasiloxan e). In this case, the ratio of the first organic silica material to the second organic silica material is preferably set between 1:9 and 9:1. The example, in the case where Rx is a vinyl group and Ry is an isopropyl group, includes a mixture obtained by mixing, at 4:3, the first organic silica material having the cyclic organic silica of n=3 in a side chain and the second organic silica material having the cyclic organic silica of n=4 in a side chain, the cyclic organic silicas of n=3 and n=4 being, respectively, (2,4,6,8-triisopropyl-2,4,6,8-trivinylcyclotrisiloxane) and (2,4,6,8-tetraisopropyl-2,4,6,8-tetravinylcyclotetrasilo xane). To the cyclic organic silica of n=3, three vinyl groups are bound, and to the cyclic organic silica of n=4, four vinyl groups are bound. By setting the mixing ratio of the two to be 4:3, it is possible to make the mixture have a stoichiometric composition in which the number of vinyl groups is made equal (12=4×3=3×4).

Furthermore, in the above-mentioned process, when forming the porous insulating film 120, an oxidizing gas such as O₂, CO₂, CO, N₂O, NO₂ or the like may be added. The gas may be introduced into a processing vessel through the same piping as that for the organic silica raw material and the carrier gas, or may be introduced into the processing vessel through another piping. In addition, the amount of the oxidizing gas is preferably not more than ½ relative to the flow amount of the carrier gas, particularly not more than ⅓.

Moreover, after subjecting the surface of the porous insulating film 120 to plasma processing, and before forming the insulating film 121, the porous insulating film 120 may be subjected to curing processing using heat, electron beams, ultraviolet light or the like. In curing by heat, the substrate temperature is preferably made to be not less than 350° C. Moreover, in curing by electron beams, the acceleration energy of electron beams is preferably set to be from 1 to 30 keV, which gives a dose amount of 0.05 to 1.0 mC/cm². Moreover, in curing processing using ultraviolet light, irradiation time is preferably set to be from 10 sec to 5 min. Meanwhile, as ultraviolet light, light of one arbitrary wavelength, light from a broadband light source, or a combination thereof (single wavelength+single wavelength, single wavelength+broadband, broadband+broadband) may be used. Furthermore, curing by heat may be performed at the same time as curing by electron beams or curing by ultraviolet light. The curing processing here is characterized by being curing processing for the porous insulating film.

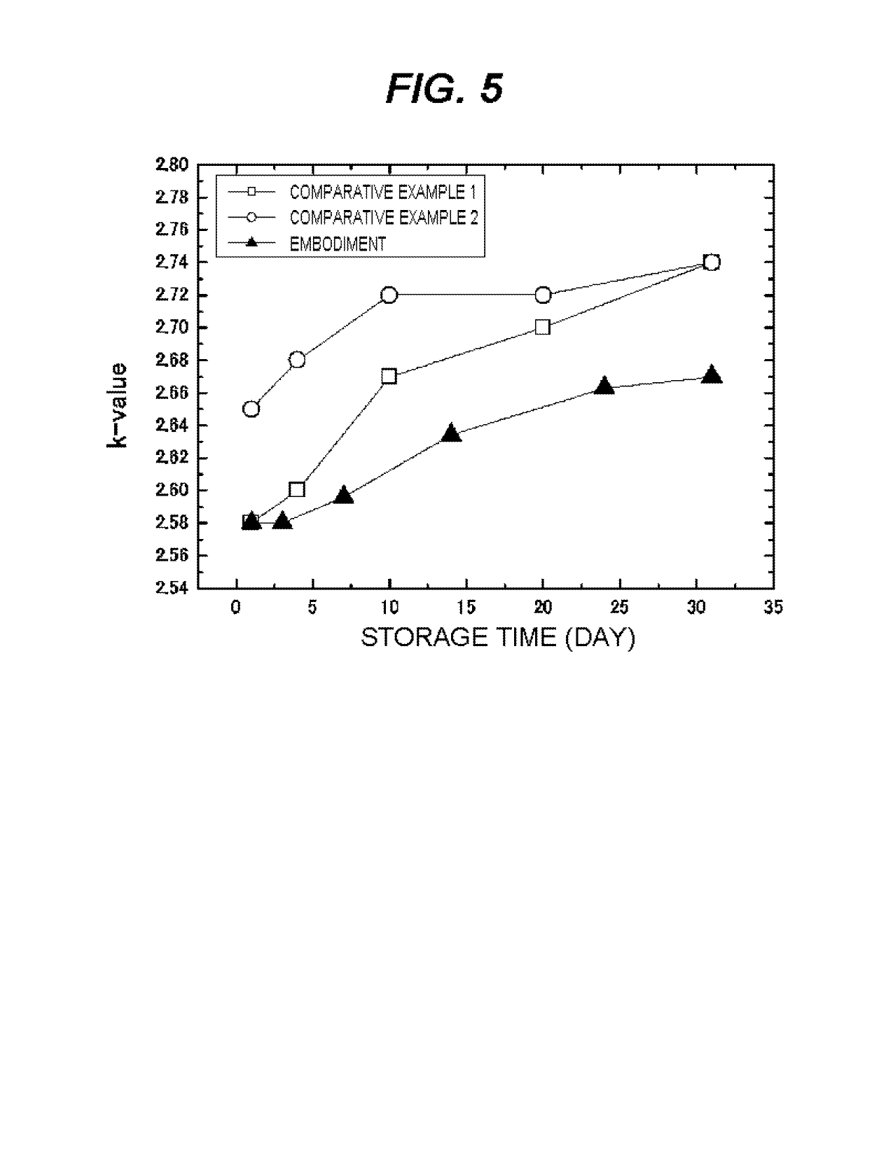

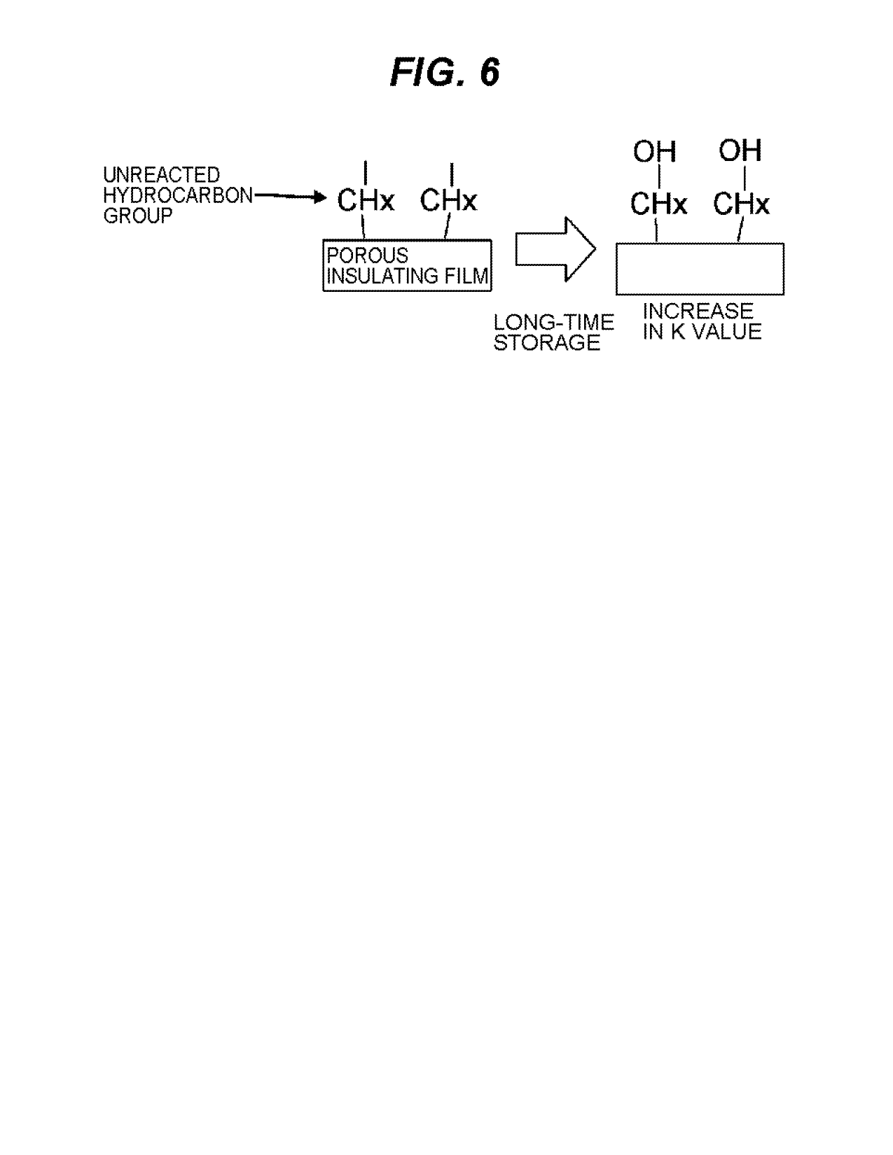

Next, the function and effect of the embodiment will be explained using FIGS. 5 and 6. FIG. 5 shows the change in the relative permittivity of the porous insulating film 120 (the practical mode) when the porous insulating film 120 is stored in a state shown in FIG. 2A. Comparative example 1 shows the change in the relative permittivity of the porous insulating film 120 when the porous insulating film 120 is stored in a state shown in FIG. 1B. In addition, Comparative example 2 shows the change in the relative permittivity of the porous insulating film 120 when the surface layer of the porous insulating film 120 in a state shown in FIG. 1B has been removed by sputtering.

In Comparative example 1, the relative permittivity of the porous insulating film 120 increases as the storage period becomes longer. The inventor considers the reason as described below. In order to lower the relative permittivity of the porous insulating film 120, it is preferable to increase the number of carbon atoms contained in the porous insulating film 120. For achieving the purpose, an organic silica raw material for forming the porous insulating film 120 is required to be caused to contain many carbons. As a result, hydrocarbon groups contained in the organic silica raw material have a large number of carbons.

Meanwhile, when the formation of the porous insulating film 120 is completed, the surface of the porous insulating film 120 is exposed to organic silica raw materials with a small degree of decomposition. As a result, the surface of the porous insulating film 120 is exposed to lots of undecomposed hydrocarbon groups. Apart of the hydrocarbon groups is, as shown in FIG. 6, deposited on (adsorbed onto) the porous insulating film 120. Hydrocarbon groups having been deposited on the porous insulating film 120 diffuse into the inside of the porous insulating film 120 along with the lapse of time. In addition, when the porous insulating film 120 is stored in the air, hydrocarbon groups in the porous insulating film 120 react with chemical species (such as an OH group) in the air. The reaction product increases the relative permittivity of the porous insulating film 120.

In contrast to this, in the embodiment, the surface of the porous insulating film 120 is processed by plasma using a reducing gas. Consequently, hydrocarbon groups deposited on the surface of the porous insulating film 120 are removed. Accordingly, as shown in FIG. 5, the increase in the relative permittivity of the porous insulating film 120 can be suppressed even when the storage period becomes long.

Meanwhile, excessive sputtering is not preferable in the surface processing of the porous insulating film 120. In Comparative example 2, the surface of the porous insulating film 120 is removed by sputtering. Consequently, hydrocarbon groups having been deposited on the surface of the porous insulating film 120 are also removed. However, apart of carbons have escaped from the surface of the porous insulating film 120, and the film 120 is modified to a film of high relative permittivity. Consequently, the initial value of the relative permittivity of the porous insulating film 120 becomes high.

In contrast to this, in the embodiment, when subjecting the surface of the porous insulating film 120 to sputtering processing, for example, He is used as an inactive gas, etc. so as to avoid sputtering as much as possible. Consequently, as shown in FIG. 5, it is possible to suppress the modification of the surface of the porous insulating film 120 and to thereby suppress the increase in the relative permittivity thereof.

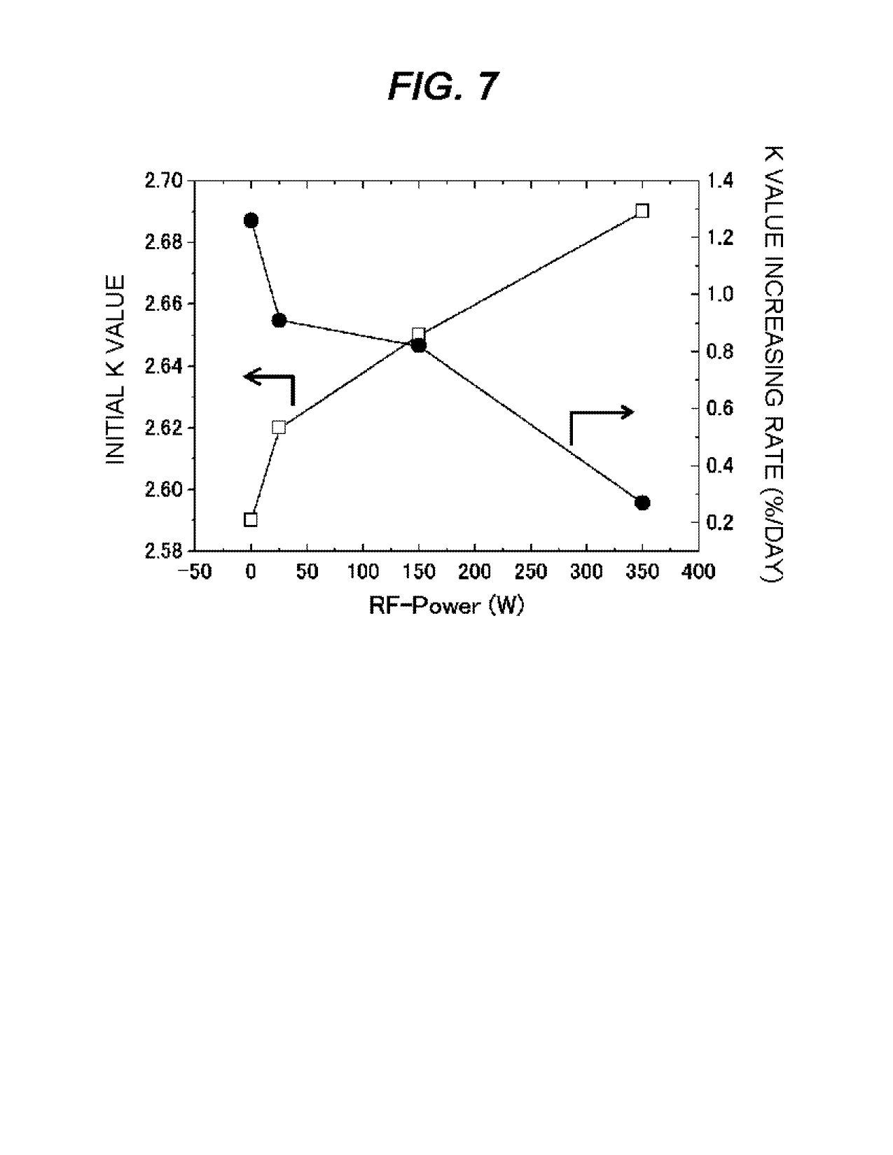

FIG. 7 shows the influence of high-frequency power on the initial value of the relative permittivity of the porous insulating film 120 and a subsequent increasing rate thereof in the plasma processing of the surface of the porous insulating film 120. When a high-frequency power for generating plasma is too low, reducing radicals or ions are not generated from the reducing gas. In this case, the relative permittivity of the porous insulating film 120 increases largely as the storage period becomes longer. In contrast, the initial value of the relative permittivity of the porous insulating film 120 becomes high. Consequently, the high-frequency power for generating plasma is required to be set to an appropriate value.

Meanwhile, whether the plasma processing according to the embodiment has been performed on the porous insulating film 120 or not can be detected by, for example, a method below.

First, the cross-section of the porous insulating film 120 is observed with a TEM (Transmission Electron Microscope). This method makes it possible to observe directly the presence or absence of a deposit on the surface of the porous insulating film 120.

In addition, the analysis of elements and chemical bonding states near the surface of the porous insulating film 120 by TEM-EELS (Electron Energy-Loss Spectroscopy) also makes it possible to observe the presence or absence of a deposit on the surface of the porous insulating film 120.

Moreover, the mass spectrometric analysis of a material having detached from the porous insulating film 120 (for example, the presence or absence of a carbonyl group) by TDS (Thermal Desorption Spectroscopy) also makes it possible to observe the presence or absence of a deposit on the surface of the porous insulating film 120.

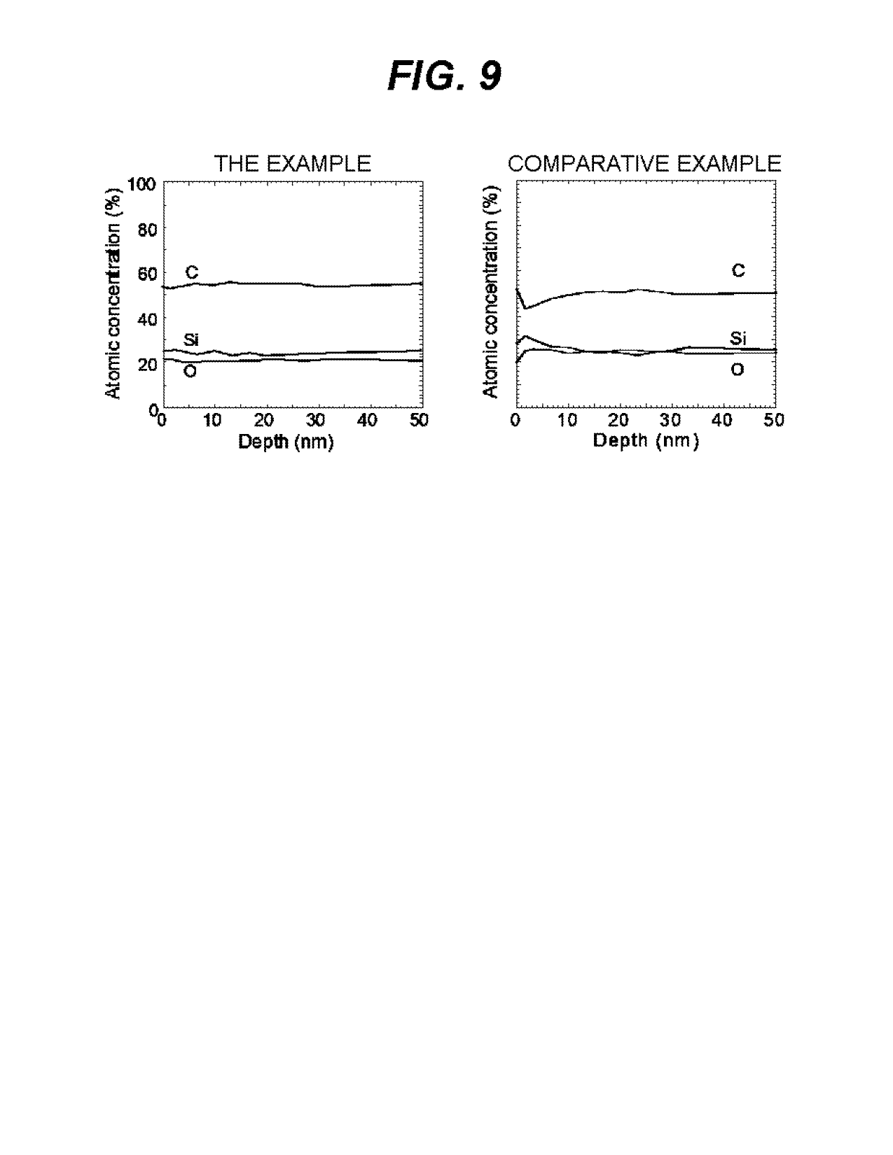

In addition, the presence or absence of a deposit on the surface of the porous insulating film 120 can be observed also by TOF-SIMS (Time of fright Secondary Ion Mass Spectroscopy), ATR-FTIR (Attenuated total reflection Fourier Transform Infrared), XPS (X-ray Photoelectron Spectroscopy), AES (Auger Electron Spectroscopy) or XRR (X-ray Reflection). Among these, in ATR-FTIR, a prism having a high refractive index is brought into contact with a part to be analyzed, and infrared light is made to enter the prism. Consequently, an evanescent wave generated at the boundary of the prism and a sample is absorbed by the sample. Therefore, by analyzing emerging light, the presence or absence of a surface-adsorbed material can be detected. FIG. 9 shows results of analysis of a film having not been subjected to the processing according to the embodiment (Comparative example) and a film having been subjected to the processing according to the embodiment, by XPS in the depth direction. In the film according to Comparative example, detachment of a carbon element caused by sputtering damage of plasma is recognized on the front surface side, but, in the film according to the embodiment, no detachment of carbon is recognized on the front surface side.

### Second Embodiment

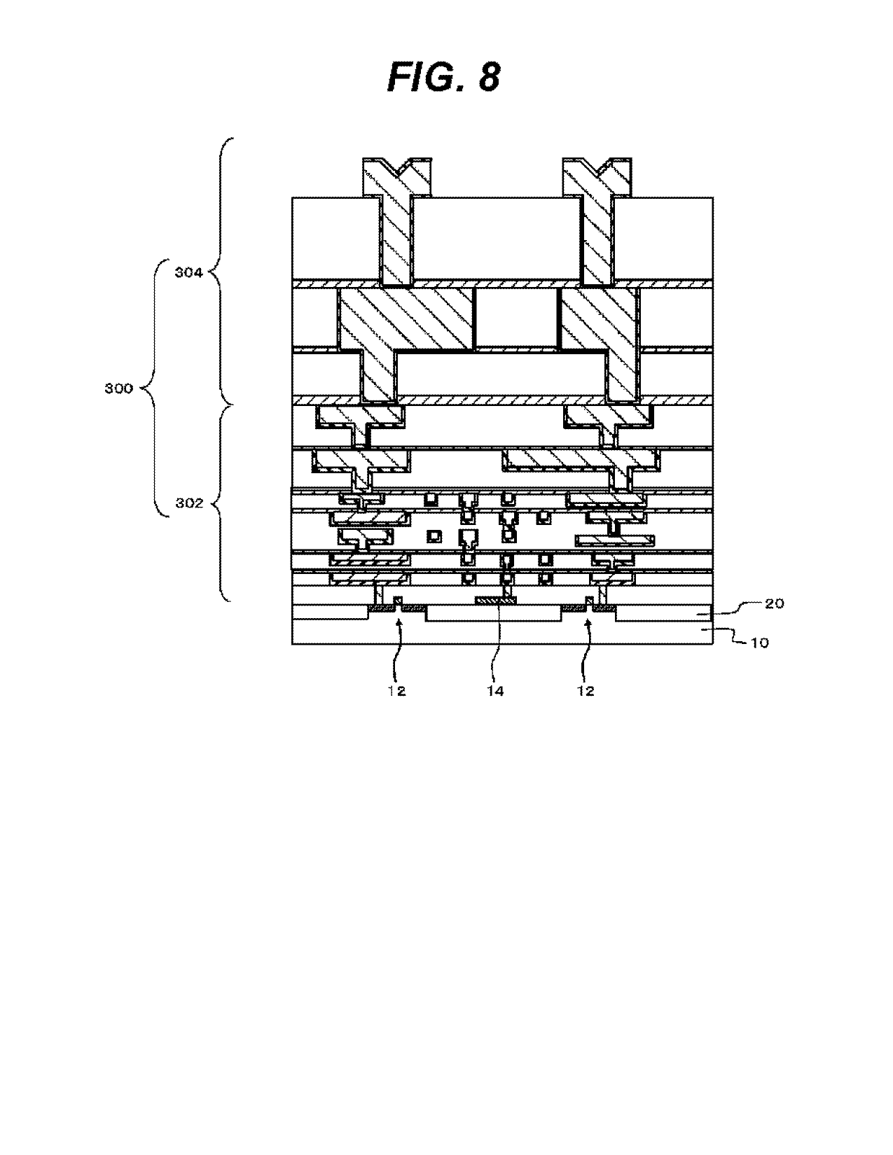

FIG. 8 is a cross-sectional view showing the configuration of the semiconductor device according to a second embodiment. The semiconductor device according to the embodiment has the followings. Over a substrate 10, an element isolation film 20 and a transistor 12 are formed. Furthermore, over the element isolation film 20, a passive element (for example, a resistive element) 14 is formed. The passive element 14 is formed in the same process as that for forming a gate electrode of the transistor 12. The substrate 10 is, for example, a silicon substrate, but is not limited to this.

Over the substrate 10, a multilayered wiring layer 300 is formed. The multilayered wiring layer 300 has a local wiring layer 302 and a global wiring layer 304. The local wiring layer 302 is a wiring layer for forming a circuit, and the global wiring layer 304 is a wiring layer for drawing power source wiring and ground wiring. The uppermost layer of the global wiring layer 304 serves as an Al wiring layer. The wiring layer includes an electrode pad. The wiring layer that forms the local wiring layer 302 and a part of layer of the global wiring layer 304 are formed by a damascene method.

In the embodiment, at least one interlayer insulating film of the local wiring layer 302, for example, interlayer insulating films constituting a wiring layer higher than the second layer are formed into the porous insulating film 120 in the first embodiment. However, all the interlayer insulating films constituting the local wiring layer 302 may be formed into the porous insulating film 120. Moreover, any of interlayer insulating films forming the global wiring layer 304 may be formed into the porous insulating film 120.

Subsequently, a method of manufacturing the semiconductor device will be explained. First, over the substrate 10, the element isolation film 20 is formed. Consequently, an element formation region is isolated. The element isolation film 20 is formed using, for example, an STI method, but may be formed using a LOCOS method. Next, over the substrate 10 located in the element formation region, a gate insulating film and a gate electrode are formed. The gate insulating film may be a silicon oxide film or may be a high permittivity film (for example, a hafnium silicate film) having a higher permittivity than the silicon oxide film. When the gate insulating film is a silicon oxide film, the gate electrode is formed from a polysilicon film. In addition, when the gate insulating film is a high permittivity film, the gate electrode is formed from a stacked film of a metal film (for example, TiN) and a polysilicon film. Furthermore, when the gate electrode is formed from a polysilicon film, in a process for forming the gate electrode, the passive element 14 is formed.

Next, on the substrate 10 located in the element formation region, extension regions of a source and a drain are formed. Subsequently, on a side wall of the gate electrode, a sidewall is formed. Next, on the substrate 10 located in the element formation region, impurity regions serving as a source and a drain are formed. In this way, over the substrate 10, the transistor 12 is formed.

Subsequently, over the element isolation film 20 and over the transistor 12, the multilayered wiring layer 300 is formed. At this time, in a process that forms any of wiring layers, the method shown in the first embodiment is used.

The embodiment can also give the same effect as that of the first embodiment. In particular, in the first embodiment, time-lag may be caused from the formation of an interlayer insulating film to the time when wiring is embedded into the interlayer insulating film, in some wiring layer. The length of the time-lag may change according to situations of a manufacturing line. According to the embodiment, even when the time-lag becomes long, as shown in FIG. 5, it is possible to suppress the increase in the relative permittivity of the interlayer insulating film. Accordingly, it is possible to suppress the generation of variation in characteristics of semiconductor devices.

Hereinbefore, the embodiments of the invention are described referring to the drawings, but these are exemplifications of the invention, and various configurations other than those described above may also be adopted.

What is claimed is:

1. A method of manufacturing a porous insulating film, comprising forming a porous insulating film by using an organic silica raw material containing a hydrocarbon group,
wherein the forming the porous insulating film includes subjecting a surface of the porous insulating film after film formation to plasma processing by using a processing gas containing an inactive gas and a reducing gas.

2. The method of manufacturing a porous insulating film according to claim 1,
wherein the inactive gas is a gas containing He or Ar.

3. The method of manufacturing a porous insulating film according to claim 1,
wherein the reducing gas contains at least one of H₂, Co and NH₃.

4. The method of manufacturing a porous insulating film according to claim 1,
wherein the porous insulating film is not exposed to the air before being subjected to the plasma processing.

5. The method of manufacturing a porous insulating film according to claim 1,
wherein a content of carbon in the porous insulating film is not less than 20% in an atom number.

6. The method of manufacturing a porous insulating film according to claim 1,
wherein an average pore diameter of the porous insulating film is not more than 1 nm.

7. The method of manufacturing a porous insulating film according to claim 1,
wherein, in the forming the porous insulating film, the porous insulating film is formed using an organic material having an unsaturated hydrocarbon group.

8. The method of manufacturing a porous insulating film according to claim 1,
wherein an abundance ratio of hydrocarbon atoms in the porous insulating film surface layer is equal to or not more than the ratio in the inside of the film.

9. The method of manufacturing a porous insulating film according to claim 1,
wherein the organic silica raw material has a cyclic organic silica skeleton shown by Formula (1) below, 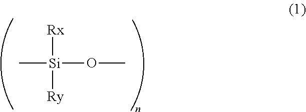
where n is 2 to 5, Rx and Ry are each any of hydrogen, an unsaturated hydrocarbon group and a saturated hydrocarbon group, and each of the unsaturated hydrocarbon group and the saturated hydrocarbon group is any of a vinyl group, an allyl group, a methyl group, an ethyl group, a propyl group, an isopropyl group, a butyl group and a tertiary butyl group.

10. The method of manufacturing a porous insulating film according to claim 9,
wherein the porous insulating film is formed using two or more kinds of the organic silica raw materials having n′s different from each other.

11. A method of manufacturing a semiconductor device, comprising:
forming a porous insulating film by using an organic silica raw material containing a hydrocarbon group;
subjecting a surface of the porous insulating film to plasma processing by using a processing gas containing an inactive gas and a reducing gas; and
forming a trench in the porous insulating film and embedding wiring into the trench.
